(19) United States
(12) Patent Application Publication
(10) Pub. No.: US 2025/0324831 A1
(43) Pub. Date: Oct. 16, 2025

(54) DISPLAY PANEL, PREPARATION METHOD AND DISPLAY DEVICE

(71) Applicant: HKC CORPORATION LIMITED, Shenzhen (CN)

(72) Inventors: Chengshun ZHU, Shenzhen (CN); Lei JIANG, Shenzhen (CN); Xueyong HUANG, Shenzhen (CN); Hejun NING, Shenzhen (CN); Chen WANG, Shenzhen (CN); Haijiang YUAN, Shenzhen (CN)

(21) Appl. No.: 19/090,879

(22) Filed: Mar. 26, 2025

(30) Foreign Application Priority Data
Apr. 16, 2024 (CN) 202410458333.2

(51) Int. Cl. H10H 20/857; H01L 25/16; H10D 86/01; H10D 86/40; H10D 86/60; H10H 29/01; H10H 29/32

(52) U.S. Cl. CPC H10H 20/857; H01L 25/167; H10D 86/0221; H10D 86/451; H10D 86/60; H10H 29/012; H10H 29/0364; H10H 29/32

(57) ABSTRACT

A display panel includes a substrate, a transistor provided on the substrate, a first protective structure, an electroless nickel immersion gold terminal, and a second protective structure. The first protective structure is provided on a side of the insulation dielectric layer away from the substrate, and the first protective structure is provided with a through hole. The electroless nickel immersion gold terminal is provided on a side of the first protective structure away from the substrate, and the electroless nickel immersion gold terminal is connected to the first pole through the through hole. The second protective structure is provided on a side of the first protective structure away from the first protective structure, and the second protective structure is opened with a groove, and the groove exposes at least a portion of the electroless nickel immersion gold terminal.

### CROSS-REFERENCE TO RELATED APPLICATIONS

This application claims priority to Chinese Patent Application No. 202410458333.2, filed Apr. 16, 2024, the entire disclosure of which is hereby incorporated herein by reference.

### TECHNICAL FIELD

The present application belongs to the field of display technology, and specifically relates to a display panel, a preparation method and a display device.

### BACKGROUND

Oxide semiconductor thin-film transistors have the advantages of high mobility, good stability, and simple fabrication process, etc. Oxide semiconductor materials represented by Indium Gallium Zinc Oxide (IGZO) are widely used in the fields of thin-film transistor liquid crystal displays (TFT-LCDs) and Active Matrix Organic Light Emitting Diode panels (AMOLEDs).

Thin-film transistors can be categorized into a top gate structure and a bottom gate structure according to the position of the gate relative to the semiconductor layer. Whether it is the bottom gate structure or the top gate structure, the metal oxide semiconductor display panels applied in Mini light-emitting diode (Mini LED) all are operated at a high temperature, high humidity and acidic environment in the latter part of the electroless nickel immersion gold process. If the film layer in the metal oxide display panel device exists micro-cracks caused by stress or other factors, in the electroless nickel immersion gold process, the micro-cracks will lead to electrical failure of the device and corrosion of the metal wiring, which will lead to display failure.

### SUMMARY

There is provided a display panel, a preparation method and a display device, capable of ensuring the integrity of the transistor and the display effect of the display panel according to embodiments of the present disclosure. The technical solution is as below:

A first aspect of the present application provides a display panel, which includes:
a substrate and a transistor provided on the substrate;
the transistor includes a gate, a semiconductor layer, a first pole and a second pole, and the gate is provided on a side of the semiconductor layer close to the substrate;
an insulation dielectric layer is provided between the gate and the semiconductor layer, the semiconductor layer is provided on a side of the insulation dielectric layer away from the substrate, and the first pole and the second pole are provided on two sides of the semiconductor layer, respectively;
the display panel further includes:
a first protective structure, provided on a side of the insulation dielectric layer away from the substrate, the first protective structure is provided with a through hole;
an electroless nickel immersion gold terminal, provided on a side of the first protective structure away from the substrate, the electroless nickel immersion gold terminal is connected to the first pole through the through hole; and
a second protective structure, provided on a side of the first protective structure away from the substrate, the second protective structure is opened with a groove, and the groove exposes at least a portion of the electroless nickel immersion gold terminal.

A second aspect of the present application provides a method of preparing the display panel according to any one of display panels, which includes:
forming a first metal layer on a substrate and patterning the first metal layer to form a gate;
forming an insulation dielectric layer and a semiconductor layer sequentially on the substrate, wherein the insulation dielectric layer covers the gate;
depositing a second metal layer on the insulation dielectric layer and the semiconductor layer, and patterning the second metal layer to form a first pole and a second pole;
forming a first protective structure on the insulation dielectric layer and the semiconductor layer, and opening a through hole in a portion corresponding to the first pole, wherein the through hole exposes a portion of the first pole;
coating the first protective structure with a third metal layer, and patterning the third metal layer to form the electroless nickel immersion gold terminal, wherein the electroless nickel immersion gold terminal is connected to the first pole through the through hole; and
forming a second protective structure on the first protective structure and opening a groove in a portion corresponding to the electroless nickel immersion gold terminal, wherein the groove exposes a portion of the electroless nickel immersion gold terminal.

A third aspect of the present application provides a display device, including a light-emitting chip and the display panel according to any one of display panels, and the light-emitting chip is connected to the electroless nickel immersion gold terminal through the groove.

It should be understood that the above general description and the detailed description that follows are merely exemplary and explanatory, and do not limit the present application.

### BRIEF DESCRIPTION OF THE DRAWINGS

The accompanying drawings herein are incorporated into and form a part of the specification, illustrate embodiments in accordance with the present application, and are used in conjunction with the specification to explain the principles of the present application. It will be apparent that the accompanying drawings in the following description are only some of the embodiments of the present application, and that other accompanying drawings may be obtained for those skilled in the art from these drawings without creative labor.

FIG. 1 is a cross-sectional structural view of a display panel provided in the first Embodiment, the fifth Embodiment, or the sixth Embodiment of the present application.

FIG. 2 is a schematic structural view of forming a gate on a substrate provided in the first Embodiment, the second Embodiment, the fifth Embodiment, or the sixth Embodiment of the present application.

FIG. 3 is a schematic structural view of forming an insulation dielectric layer on the substrate provided in the first Embodiment, the second Embodiment, the fifth Embodiment, or the sixth Embodiment of the present application.

FIG. 4 is a schematic structural view of forming a semiconductor layer on the insulation dielectric layer provided by the first Embodiment, the second Embodiment, the fifth Embodiment, or the sixth Embodiment of the present application.

FIG. 5 is a schematic structural view of forming a first pole and a second pole on an insulation dielectric layer provided in the first Embodiment, the second Embodiment, the fifth Embodiment, or the sixth Embodiment of the present application.

FIG. 6 is a schematic structural view of forming a through hole on the first protective structure provided in the first Embodiment, the second Embodiment, the fifth Embodiment, or the sixth Embodiment of the present application.

FIG. 7 is a schematic structural view of forming an electroless nickel immersion gold within the through hole provided in the first Embodiment, the second Embodiment, the fifth Embodiment, or the sixth Embodiment of the present application.

FIG. 8 is a schematic structural view of forming a second protective structure on the first protective structure provided in the first Embodiment, the fifth Embodiment, or the sixth Embodiment of the present application.

FIG. 9 is a schematic structural view of forming a third protective structure between the first protective structure and the second protective structure provided in the second Embodiment, the fifth Embodiment, or the sixth Embodiment of the present application.

FIG. 10 is a schematic structural view of that a transistor provided in the third Embodiment or the sixth Embodiment of the present application is of a top gate type.

FIG. 11 is a schematic structural view of forming a semiconductor layer on the first insulation dielectric layer provided in the third Embodiment, the fourth Embodiment, or the sixth Embodiment of the present application.

FIG. 12 is a schematic structural view of forming a second insulation dielectric layer and a gate on the semiconductor layer provided in the third Embodiment, the fourth Embodiment, or the sixth Embodiment of the present application.

FIG. 13 is a schematic structural view of forming a seventh insulation protective layer on the first insulation dielectric layer provided in the third Embodiment, the fourth Embodiment, or the sixth Embodiment of the present application.

FIG. 14 is a schematic structural view of connecting the first pole and the second pole to the semiconductor layer provided in the third Embodiment, the fourth Embodiment, or the sixth Embodiment of the present application.

FIG. 15 is a schematic structural view of forming the first protective structure on the seventh insulation protective layer of the present application.

FIG. 16 is a schematic structural view of connecting the electroless nickel immersion gold terminal to the first pole provided in the third Embodiment, the fourth Embodiment, or the sixth Embodiment of the present application.

FIG. 17 is a schematic structural view of forming the second protective structure on the first protective structure provided in the third Embodiment, the fourth Embodiment, or the sixth Embodiment of the present application.

FIG. 18 is a schematic structural view of forming a third protective structure between the first protective structure and the second protective structure provided in the fourth Embodiment or the sixth Embodiment of the present application.

FIG. 19 is a flowchart of preparing a display panel provided in the first Embodiment, the fifth Embodiment, or the sixth Embodiment of the present application.

### DETAILED DESCRIPTION OF THE EMBODIMENTS

Embodiments will now be described more fully with reference to the accompanying drawings. However, the embodiments can be implemented in a variety of forms and should not be construed as limitation to the examples set forth herein; rather, these embodiments makes the present application more comprehensive and complete and conveys the idea of the embodiments in a comprehensive manner to those skilled in the art.

In the present application, the terms “first” and “second” are used for descriptive purposes only and are not to be construed as indicating or implying relative importance or implicitly specifying the number of technical features indicated. As a result, a feature defined with the terms “first” and “second” may expressly or implicitly include one or more such features. In the description of the present application, “more than one” means two or more, unless otherwise expressly and specifically limited.

In the present application, unless otherwise expressly specified and limited, the terms “assembly”, “connection”, etc. are to be broadly understood, e.g., as a fixed connection, a detachable connection, formed integratedly, a mechanical connection, or an electrical connection, or a direct connection or an indirect connection through an intermediate medium, a communication within two elements or an interaction between two elements. For those skilled in the art, the specific meanings of the above terms in the present application may be understood based on actual situations.

In addition, the described features, structures, or characteristics may be combined in one or more embodiments in any suitable manner. In the following description, many specific details are provided thereby giving a full understanding of the embodiments of the present application. However, those skilled in the art will realize that it is possible to practice the technical embodiments of the present application without one or more of the specific details, or that other methods, components, devices, steps, etc. may be employed. In other cases, the well-known methods, devices, implementations, or operations are not shown or described in detail to avoid blurring aspects of the present application.

### First Embodiment

The first Embodiment of the present application provides a display panel 10, the display panel 10 may be a Mini Light-Emitting Diode (Mini LED).

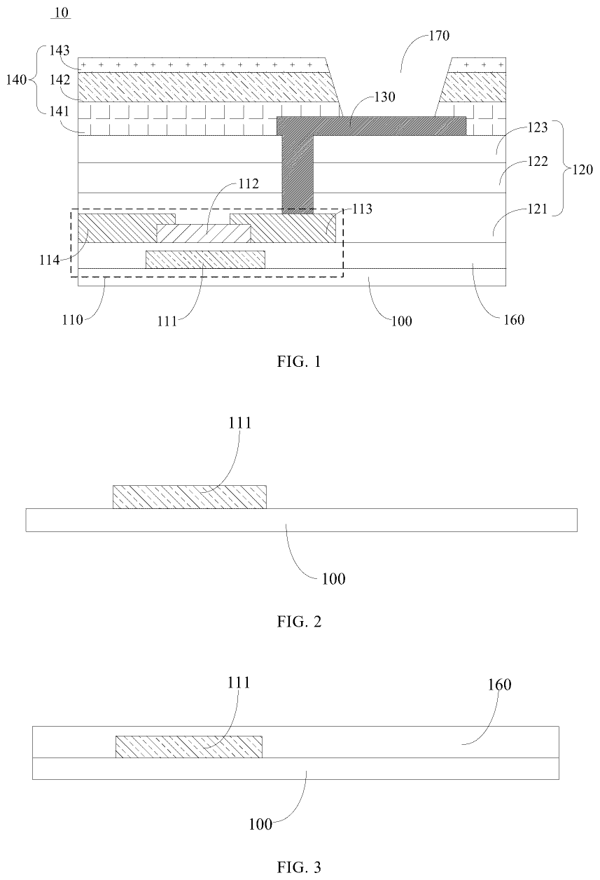

Referring to FIG. 1, the display panel 10 may include a substrate 100, a transistor 110, a first protective structure 120, an electroless nickel immersion gold terminal 130, and a second protective structure 140. The transistor 110 is provided on the substrate 100, and includes a gate 111, a semiconductor layer 112, and a first electrode 113 and a second electrode 114 provided in the same layer. The first protective structure 120 is provided with a through hole 150, and the through hole 150 exposes a portion of the first electrode 113, so as to facilitate electrical connection of the electroless nickel immersion gold terminal 130 to the first pole 113. The electrical signals are transmitted through the gate 111, the second pole 114, the semiconductor layer 112, and the first pole 113. The electroless nickel immersion gold terminal 130 is electrically connected to the light-emitting chip. In order to avoid damage to the transistor 110 during the electroless nickel immersion gold process, the second protective structure 140 protects the transistor 110 from erosion by the chemical liquid during the electroless nickel immersion gold process, which can effectively limit the region of the electroless nickel immersion gold terminal 130, and improve the stability of the electroless nickel immersion gold process.

The structure of the display panel 10 will be specifically described below in connection with the accompanying drawings.

The display panel 10 may include a substrate 100, and the substrate 100 may be made of any one of a plastic, an FR-4 grade material, a resin, a glass, a quartz, a polyimide, or a Polymethyl Methacrylate (PMMA).

The display panel 10 may also include a plurality of sub-pixels, and the plurality of sub-pixels may be arrayed on the substrate 100 in a row direction and a column direction.

The display panel 10 may also include a plurality of transistors 110 provided on the substrate 100, and one transistor 110 corresponds to one sub-pixel.

The transistor 110 includes a gate 111, a semiconductor layer 112, and a first pole 113 and a second pole 114 provided in the same layer. An insulation dielectric layer 160 may be provided between the gate 111 and the semiconductor layer 112 to insulate the gate 111 from the semiconductor layer 112. The first pole 113 and the second pole 114 may be connected to the source-drain doped regions of the semiconductor layer 112, respectively. Specifically, corresponding connection relationships between the first pole 113, the second pole 114 and the source-drain doped regions of the semiconductor layer 112, will not be detailed herein.

For example, as shown in FIGS. 2 to 5, the transistor 110 of an embodiment of the present application may be of the bottom gate type, i.e., the gate 111 may be first formed on the substrate 100. Then, an insulation dielectric layer 160 is formed on the substrate 100, and the insulation dielectric layer 160 covers the gate 111. Thereafter, a semiconductor layer 112 is formed on a side of the insulation dielectric layer 160 away from the substrate 100, i.e., the semiconductor layer 112 is located on a side of the gate 111 away from the substrate 100, and the semiconductor layer 112 overlaps with a positive projection of the gate 111 on the substrate 100. Exemplarily, the positive projection of the semiconductor layer 112 on the substrate 100 may be located within the positive projection of the gate 111 on the substrate 100. The first pole 113 and the second pole 114 may be formed after the semiconductor layer 112 is formed. At least a portion of the first pole 113 may be lapped on one doped region of the source-drain doped region of the semiconductor layer 112. At least a portion of the second pole 114 may be lapped on another doped region of the source-drain doped region of the semiconductor layer 112.

The gate 111 may be provided as a single layer, a double layer, a multilayer metal alloy or a monolithic metal, and the metal alloy or monolithic metal includes a copper Cu, a molybdenum Mo, an aluminum Al, a titanium Ti, a niobium Nb, a magnesium Mg, but is not limited to this. A first metal layer is deposited on the substrate 100 by a magnetron sputtering method, and the first metal layer is patterned to obtain the gate 111. The patterning process includes coating glue, exposure, development, and wet etching, etc.

After the gate 111 is formed on the substrate 100, an insulation dielectric layer 160 is formed on the surface of the gate 111 by a chemical vapor deposition method. The insulation dielectric layer 160 includes at least two of silicon oxide, silicon nitride, and silicon oxynitride, i.e., the insulation dielectric layer 160 is at least a composite film layer including the above silicon oxide, silicon nitride, and silicon oxynitride materials.

The insulation dielectric layer 160 is one of silicon nitride and silicon oxynitride close to the gate 111, and the silicon oxide is close to the top of the gate 111.

Further, a metal oxide semiconductor is deposited on the insulation dielectric layer 160 by the magnetron sputtering method and patterned to form a semiconductor layer 112. The semiconductor layer 112 contains elements including, but not limited to, indium (In), gallium (Ga), zinc (Zn), oxygen (O), etc. The semiconductor layer 112 has a carrier concentration of 5 to 30 cm²/V*S.

It should be noted that a metal oxide semiconductor film is formed on the insulation dielectric layer 160, and then it is subjected to coating glue, exposure, development, dry etching and stripping. Then the metal oxide semiconductor is patterned by the wet etching and stripping, and finally the patterned substrate 100 is subjected to an annealing treatment at 350° C. to 500° C. for 30 min to 65 min. The annealing temperature may be 350° C., 400° C., 450° C., 500° C., and the time may be 30 min, 40 min, 45 min, 50 min, 55 min, 60 min, 65 min, etc.

Further, the second metal layer is deposited on the insulation dielectric layer 160 by the magnetron sputtering method, and the second metal layer is patterned to obtain the first pole 113 and the second pole 114 provided in the same layer. The first pole 113 and the second pole 114 are spaced from each other, and the first pole 113 and the second pole 114 are lapped on two opposite sides of the semiconductor layer 112, respectively.

It is to be noted that, in the present application, “provided in the same layer” refers to a layer structure formed by using the same film forming process to form a film layer for forming a specific pattern, and then using the same mask to form a layer structure by a single composition process. That is, one mask corresponds to one composition process. According to the different specific graphics, one composition process may include multiple exposure, development or etching process, and the specific graphics in the formed layer structure can be continuous or discontinuous. These specific graphics may also be at different heights or have different thicknesses, thereby simplifying the fabrication process, saving the fabrication cost, and improving the production efficiency.

In addition, the first pole 113 and second pole 114 may be provided as a single layer, a double layer, a multilayer metal alloy or a monolithic metal. The metal alloy or the monolithic metal includes Cu, Mo, Al, Ti, and Nb, and then the second metal layer is patterned by the coating glue, exposure, development, and wet etching and stripping to obtain the first pole 113 and the second pole 114.

After the first pole 113 and the second pole 114 are formed, see FIG. 6, a first protective structure 120 is formed on the insulation dielectric layer 160, and the first protective structure 120 covers the first pole 113, the second pole 114, and the semiconductor layer 112 to protect the transistor 110 in the subsequent preparation of the electroless nickel immersion gold terminal 130, to ensure the integrity and stability of the transistor 110.

As shown in FIG. 6, the first protective structure 120 is provided with a through hole 150, and the through hole 150 can expose a portion of the first pole 113, so as to facilitate the subsequent electrical connection of the electroless nickel immersion gold terminal 130 to the first pole 113, thereby realizing data transmission.

In the embodiment of the present application, the first protective structure 120 includes at least two layers of insulation protective layers, which can both play the role of insulation and protecting the transistor 110.

As shown in FIG. 6, the first protective structure 120 includes a fourth insulation protective layer 121, a fifth insulation protective layer 122, and a sixth insulation protective layer 123. After the first electrode 113 and the second electrode 114 are formed, the fourth insulation protective layer 121, the fifth insulation protective layer 122, and the sixth insulation protective layer 123 are sequentially deposited on the surfaces thereof by a chemical vapor deposition and coating method. The fourth insulation protective layer 121 covers the insulation dielectric layer 160, the first pole 113, the semiconductor layer 112, and the second pole 114.

The fourth insulation protective layer 121 includes at least one of silicon oxide and silicon nitride, or may be formed of other materials. After the fourth insulation protective layer 121 is formed, it is subjected to an annealing treatment at 240° C. to 300° C. for 30 min to 65 min. The annealing temperature may be 240° C., 260° C., 280° C., 300° C., and the time may be 30 min, 40 min, 45 min, 50 min, 55 min, 60 min, 65 min, etc.

Then, the fifth insulation protective layer 122 is coated on the fourth insulation protective layer 121, and the fifth insulation protective layer 122 is a photopolymer resin material with a high sensitivity and high adhesion class.

The sixth insulation protective layer 123 is deposited on the fifth insulation protective layer 122, and the sixth insulation protective layer 123 may be one or more structures of silicon oxide, silicon nitride, and organic insulation film.

Finally, a through hole 150 for exposing a portion of the first pole 113 is formed after the coating glue, exposure, and development, and the dry etching treatment are performed on the fourth insulation protective layer 121, the fifth insulation protective layer 122, and the sixth insulation protective layer 123, and the electroless nickel immersion gold terminal 130 is connected to the first pole 113 through the through hole 150.

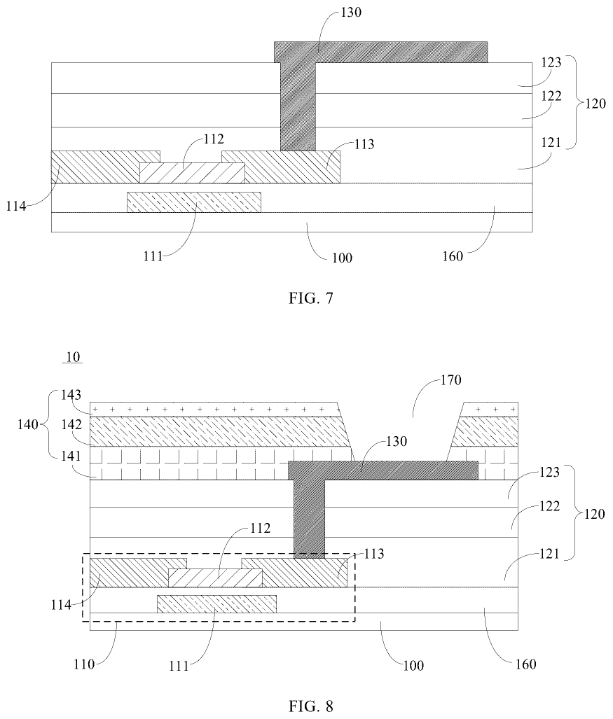

Further, as shown in FIG. 7, a third metal layer is coated on the sixth insulation protective layer 123 by the magnetron sputtering method. A portion of the metal in the third metal layer falls into the through hole 150, and then the third metal layer is patterned to obtain the electroless nickel immersion gold terminal 130. The third metal layer is made of a composite structure of Cu, Mo, Al, Ti, and Nb. A topmost layer of the electroless nickel immersion gold terminal 130 is a Cu film layer to precipitate Cu in the subsequent electroless nickel immersion gold process, so as to subsequently be soldered to the light-emitting chip.

Patterning the third metal layer includes performing the coating glue, exposure, development, and wet etching and stripping on the third metal layer.

Referring to FIG. 8, finally, in order to avoid damage to the transistor 110 during the electroless nickel immersion gold process, a second protective structure 140 is formed on the electroless nickel immersion gold terminal 130 after the electroless nickel immersion gold terminal 130 is formed. The second protective structure 140 is opened with a groove 170 which exposes at least a portion of the electroless nickel immersion gold terminal 130, so as to facilitate the connection of the electroless nickel immersion gold terminal 130 to the light-emitting chip for controlling light emitting of the light-emitting chip.

The second protective structure 140 includes at least two layers of insulation protective layers sequentially provided in a thickness direction of the substrate 100, so as to improve the protective effect on the transistor 110, to ensure that the transistor 110 will not be damaged in the electroless nickel immersion gold process, to improve the working stability of the transistor 110, and further to improve the display stability of the display panel 10.

In an embodiment of the present application, as shown in FIG. 8, the second protective structure 140 includes a first insulation protective layer 141, a second insulation protective layer 142, and a third insulation protective layer 143 sequentially provided in the thickness direction of the substrate 100. The first insulation protective layer 141 is provided on a side of the sixth insulation protective layer 123 away from the substrate 100, and covers a portion of the electroless nickel immersion gold terminal 130.

The first insulation protective layer 141 and the third insulation protective layer 143 include the same material, and the first insulation protective layer 141 and the third insulation protective layer 143 are made of the material different from that of the second insulation protective layer 142, to improve the protection of the first pole 113, the semiconductor layer 112, the gate 111, and the second pole 114.

The first insulation protective layer 141 includes a single film structure of silicon oxide, silicon nitride, silicon oxynitride, aluminum oxide, or a combination thereof, but is not limited thereto. The second insulation protective layer 142 is an organic film layer, which is mainly a high sensitivity, high adhesion class of photopolymer resin material. The second insulation protective layer 142 mainly serves as a leveling effect to provide a flat surface for the subsequent electroless nickel immersion gold process and welding process. The third insulation protective layer 143 includes a single film structure of silicon oxide, silicon nitride, silicon oxynitride, aluminum oxide, or a combination thereof, but is not limited thereto. That is, the first insulation protective layer 141 and the third insulation protective layer 143 are an inorganic layer, and the second insulation protective layer 142 is an organic layer, and different membrane layers can improve the protective performance of the second protective structure 140, and can better protect the transistor 110.

The method of forming the groove 170 includes coating glue, exposure, development, and dry etching and stripping. Moreover, the cross-sectional area of the groove 170 is gradually increased in a direction from the first insulation protective layer 141 to the third insulation protective layer 143, i.e., an aperture diameter of the groove 170 gradually increases, as shown in FIG. 8, such that the light-emitting chip can be fixed in the groove 170, and it ensures that the light-emitting chip will not be skewed, so as to ensure the display effect.

It should be noted that the groove 170 can penetrate the three layers of insulation protective layers by one photolithographic etching, and it is not difficult to implement the process.

The first insulation protective layer 141, the second insulation protective layer 142, and the third insulation protective layer 143 in the second protective structure 140 can improve the protection of the transistor 110, thereby avoiding electrical failure of the transistor 110 and corrosion of the metal wires of the transistor 110 under high temperature, high humidity, and acidic conditions in the electroless nickel immersion gold process, and ensuring the integrity and stability of the transistor 110. Moreover, it can effectively limit the region of the electroless nickel immersion gold terminal 130, thereby improving the stability of the electroless nickel immersion gold process.

### Second Embodiment

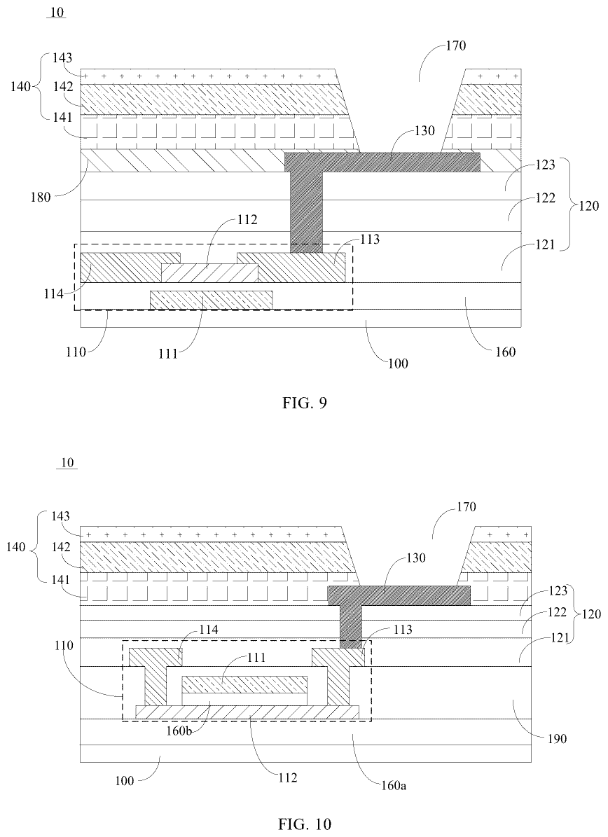

The difference between second Embodiment of the present application and first Embodiment is that the display panel 10 further includes a third protective structure 180, which is provided between the first insulation protective layer 141 and the sixth insulation protective layer 123, and the third protective structure 180 covers a portion of the electroless nickel immersion gold terminal 130, as shown in FIG. 9.

In an embodiment of the present application, the third protective structure 180 may be a metal oxide protective layer, which may be made of the same material as the semiconductor layer 112, and the elements contained in the metal oxide protective layer include, but are not limited to, indium (In), gallium (Ga), zinc (Zn), oxygen (O), etc. The third protective structure 180 mainly serves to prevent the first insulation protective layer 141 from being directly deposited in the electroless nickel immersion gold terminal 130, whose film layer easily falls off due to affection by high temperatures, thereby resulting in the electroless nickel immersion gold terminal 130 to not be able to precipitate copper well, and then affecting the soldering of the electroless nickel immersion gold terminal 130 to the light-emitting chip.

It can be understood that if the first insulation protective layer 141 adopts a low-temperature film-forming process, it is possible to optimize the thickness of the display panel 10 without adding the third protective structure 180.

In addition, the third protective structure 180, the first insulation protective layer 141, the second insulation protective layer 142, and the third insulation protective layer 143 are sequentially formed on the sixth insulation protective layer 123, and then the third protective structure 180, the first insulation protective layer 141, the second insulation protective layer 142, and the third insulation protective layer 143 are patterned by coating glue, exposure, development, and dry etching and stripping, to form a groove 170 which exposes a portion of the electroless nickel immersion gold terminal 130.

### Third Embodiment

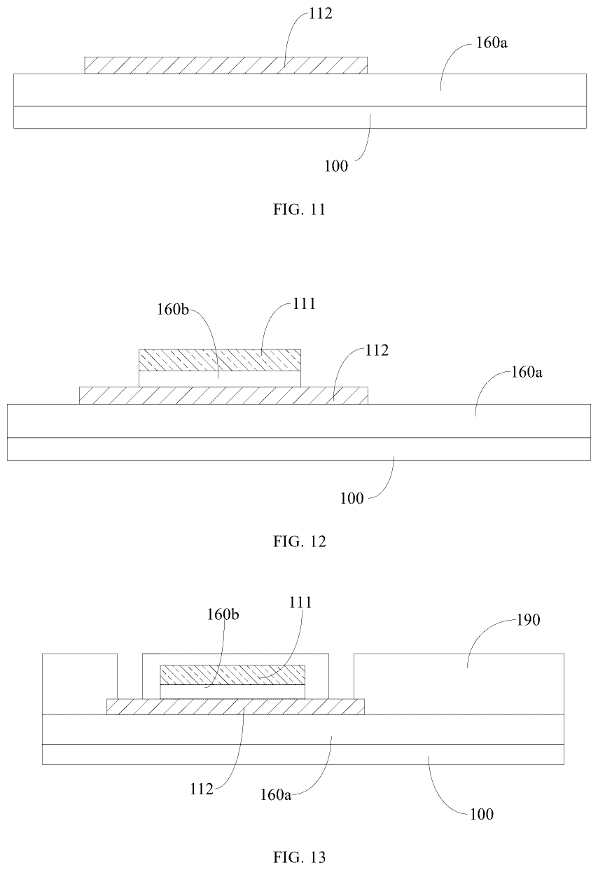

The third Embodiment of the present application differs from the first Embodiment in that the third Embodiment uses the transistor 110 of a top gate type, as shown in FIG. 10.

The top gate type of the transistor 110 is prepared as follows:

A film is first formed on the substrate 100 by the magnetron sputtering method, and then a bottom gate is formed by using a patterning process of coating glue, exposure, development, and etching and stripping, and the bottom gate may be set as a single layer, a double layer, a multilayer metal alloy or a monolithic metal, and the metal alloy or monolithic metal include Cu, Mo, Al, Ti, Nb, and Mg.

The first insulation dielectric layer 160a is then formed on the bottom gate by using the chemical vapor deposition method, and the first insulation dielectric layer 160a includes at least two of silicon oxide, silicon nitride, and silicon oxynitride, i.e., the insulation dielectric layer 160 is at least a composite film layer made of the above silicon oxide, silicon nitride, and silicon oxynitride materials.

The first insulation dielectric layer 160a is one of silicon nitride and silicon oxynitride close to the bottom gate, and the silicon oxide film layer is close to the top of the first insulation dielectric layer 160a.

A metal oxide semiconductor is then formed on a surface of the first insulation dielectric layer 160a by the magnetron sputtering method, and the semiconductor includes indium (In), gallium (Ga), zinc (Zn), oxygen (O), etc., but is not limited thereto. The patterned semiconductor layer 112 is then formed by coating glue, exposure, development, and dry etching and stripping, as shown in FIG. 11.

Referring to FIG. 12, a second insulation dielectric layer 160b is formed by chemical vapor deposition, and includes a silicon oxide material. The second insulation dielectric layer 160b is subjected to an annealing treatment at 260° C. to 340° C. for 45 min to 75 min. The annealing temperature may be 260° C., 280° C., 300° C., 340° C., and the time may be 45 min, 50 min, 55 min, 60 min, 65 min, 70 min, 75 min, etc. After the annealing treatment is performed, the second insulation dielectric layer 160b is patterned to form a hole pattern by coating glue, exposure, development, and dry etching and stripping.

Referring to FIG. 12, a first metal layer is formed on the first insulation dielectric layer 160a by the magnetron sputtering method, and patterning treatment such as coating glue, exposure, development, etching, etc. is performed on the first metal layer obtain a top gate. The top gate may be provided as a single layer, a double layer, a multilayer metal synthesis or a monolithic metal, and the metal alloy or monolithic metal include Cu, Mo, Al, Ti, Nb, and Mg, but is not limited to this. The top gate is connected to the bottom gate through a pattern hole formed in the second insulation dielectric layer 160b.

The second insulation dielectric layer 160b is then etched by dry etching to expose a semiconductor layer 112 not covered by the top gate, and the exposed semiconductor layer 112 is bombarded by a gas plasma to process the exposed semiconductor layer 112. The gas includes helium, argon, but is not limited to, as long as it is capable of processing the semiconductor layer 112.

Referring to FIG. 13, a seventh insulation protective layer 190 is finally formed on the first insulation dielectric layer 160a, and the seventh insulation protective layer 190 covers the semiconductor layer 112, the second insulation dielectric layer 160b, and the top gate. The seventh insulation protective layer 190 includes at least one of silicon oxide and silicon nitride, and the seventh insulation protective layer 190 may be either a single layer structure or a composite layer structure. A hole patterning of the seventh insulation protective layer 190 is formed by coating glue, exposure, development, and dry etching and stripping, and the opened hole exposes a portion of the semiconductor layer 112.

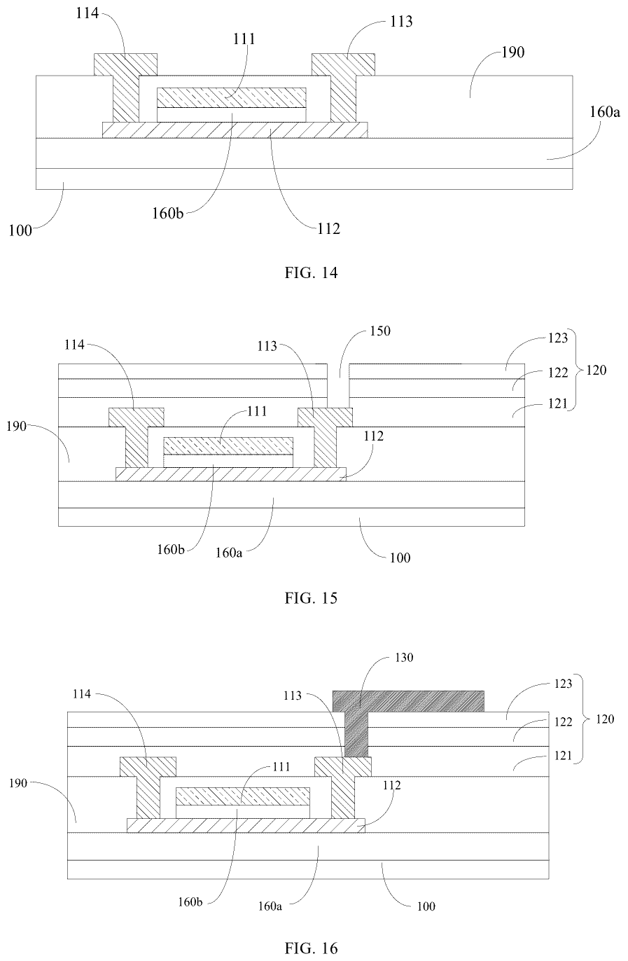

Referring to FIG. 14, a second metal layer is then coated on the seventh insulation protective layer 190 and patterned by coating glue, exposure, development, dry etching and stripping to form the first pole 113 and the second pole 114, which are made of the same material as that of the top gate, and the first pole 113 and the second pole 114 are connected to the semiconductor layer 112 at the bottom.

Referring to FIG. 15, the first protective structure 120 is then formed on the seventh insulation protective layer 190, i.e., a fourth insulation protective layer 121, a fifth insulation protective layer 122, and a sixth insulation protective layer 123 are sequentially deposited on the seventh insulation protective layer 190. The fourth insulation protective layer 121, the fifth insulation protective layer 122, and the sixth insulation protective layer 123 are deposited using the same material and deposition method as in the first Embodiment.

Please refer to FIG. 15, the fourth insulation protective layer 121, the fifth insulation protective layer 122, and the sixth insulation protective layer 123 are process to form a hole to expose a portion of the first pole 113.

Referring to FIG. 16, a third metal layer is coated on the sixth insulation protective layer 123 by the magnetron sputtering method, and the third metal layer is made of the same material as the third metal layer in the first Embodiment. The third metal layer is then patterned to obtain the electroless nickel immersion gold terminal 130.

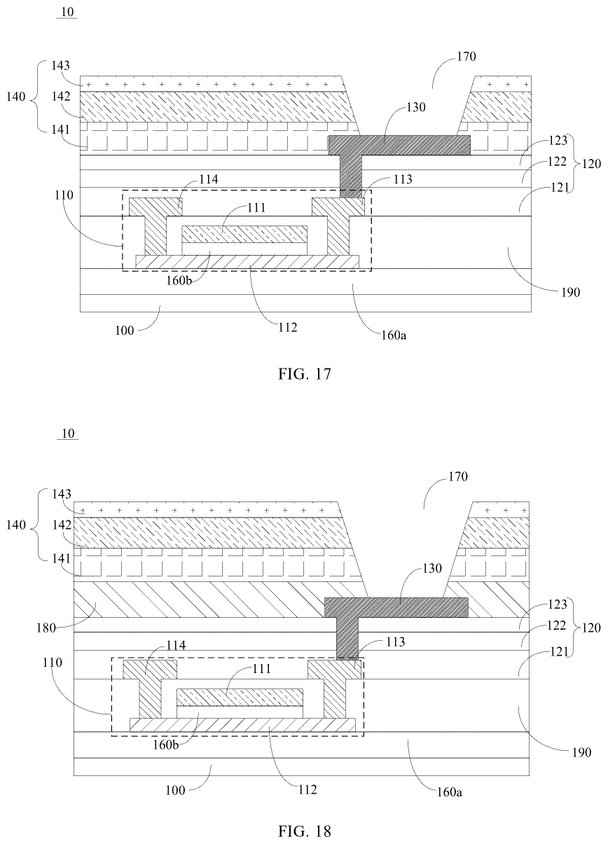

Referring to FIG. 17, the second protective structure 140 is finally formed sequentially on the sixth insulation protective layer 123, i.e., the first insulation protective layer 141, the second insulation protective layer 142, and the third insulation protective layer 143 are deposited sequentially on the sixth insulation protective layer 123, and a dry etching process is performed on the first insulation protective layer 141, the second insulation protective layer 142, and the third insulation protective layer 143 to obtain the groove 170.

### Fourth Embodiment

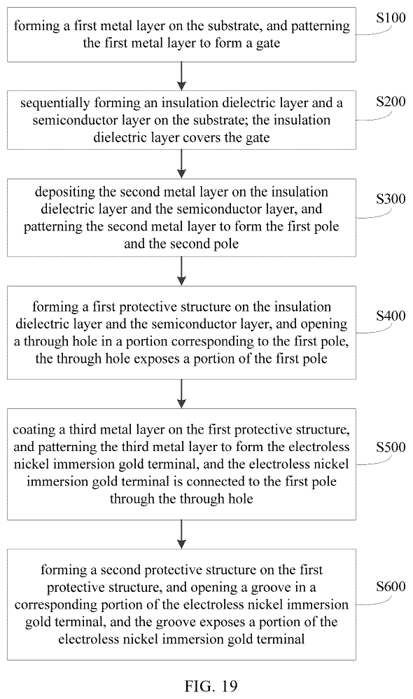

The fourth Embodiment of the present application differs from the third Embodiment in that the display panel 10 further includes a third protective structure 180, the third protective structure 180 is provided between the first insulation protective layer 141 and the sixth insulation protective layer 123, and the third protective structure 180 covers a portion of the electroless nickel immersion gold terminal 130. The third protective structure 180 is made of the same material as the third protective structure 180 in the second Embodiment, as shown in FIG. 18.

### Fifth Embodiment

Referring to FIG. 19, the fifth Embodiment of the present application provides a method of preparing the display panel 10 in the first Embodiment. The method includes:

Step S100, forming a first metal layer on the substrate 100, and patterning the first metal layer to form a gate 111, as shown in FIG. 2.

The gate 111 may be provided as a single layer, a double layer, a multilayer metal synthesis, or a monolithic metal, and the metal alloy or monolithic metal includes Cu, Mo, Al, Ti, Nb, and Mg, but is not limited to this. The first metal layer is deposited on the substrate 100 by the magnetron sputtering method, and the first metal layer is patterned to obtain the gate 111. This patterning process includes coating glue, exposure, development, and wet etching.

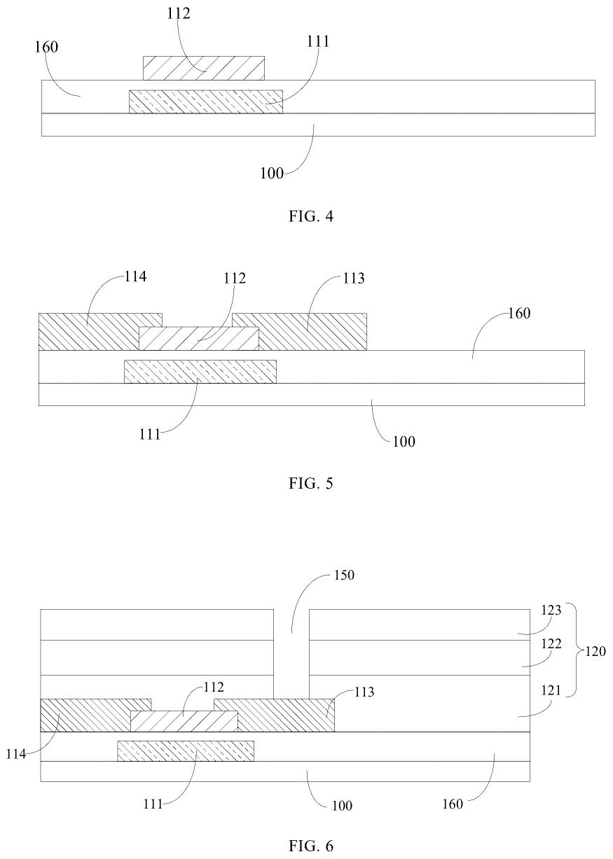

Step S200, sequentially forming an insulation dielectric layer 160 and a semiconductor layer 112 on the substrate 100. The insulation dielectric layer 160 covers the gate 111, as shown in FIGS. 3 and 4.

After the gate 111 is formed on the substrate 100, the insulation dielectric layer 160 is formed on the surface of the gate 111 by a chemical vapor deposition method. The insulation dielectric layer 160 includes at least two of silicon oxide, silicon nitride, and silicon oxynitride; i.e., the insulation dielectric layer 160 is at least a composite film layer made of the above silicon oxide, silicon nitride, and silicon oxynitride materials.

The insulation dielectric layer 160 is one of silicon nitride, silicon oxynitride close to the gate 111, and the silicon oxide is close to the top of the gate 111.

Further, a metal oxide semiconductor is deposited on the insulation dielectric layer 160 by a magnetron sputtering method and patterned thereon to form a semiconductor layer 112 The semiconductor layer 112 contains elements including, but not limited to, indium (In), gallium (Ga), zinc (Zn), oxygen (O), etc. The semiconductor layer 112 has a carrier concentration of 5 to 30 cm²/V*S.

It should be noted that a metal oxide semiconductor film is formed on the insulation dielectric layer 160, and then it is subjected to coating glue, exposure, development, dry etching and stripping. Then the metal oxide semiconductor is patterned by the wet etching and stripping, and finally the patterned substrate 100 is subjected to an annealing treatment at 350° C. to 500° C. for 30 min to 65 min. The annealing temperature may be 350° C., 400° C., 450° C., 500° C., and the time may be 30 min, 40 min, 45 min, 50 min, 55 min, 60 min, 65 min, etc.

Step S300, depositing the second metal layer on the insulation dielectric layer 160 and the semiconductor layer 112, and patterning the second metal layer to form the first pole 113 and the second pole 114, as shown in FIG. 5.

The second metal layer is deposited on the insulation dielectric layer 160 by the magnetron sputtering method, and the second metal layer is patterned to obtain the first pole 113 and the second pole 114 provided in the same layer. The first pole 113 and the second pole 114 are spaced from each other, and the first pole 113 and the second pole 114 are lapped on two opposite sides of the semiconductor layer 112, respectively.

The first pole 113 and second pole 114 may be provided as a single layer, a double layer, a multilayer metal alloy or a monolithic metal. The metal alloy or the monolithic metal includes Cu, Mo, Al, Ti, and Nb, and then the second metal layer is patterned by the coating glue, exposure, development, and wet etching and stripping to obtain the first pole 113 and the second pole 114.

Step S400, forming a first protective structure 120 on the insulation dielectric layer 160 and the semiconductor layer 112, and opening a through hole 150 in a portion corresponding to the first pole 113, the through hole 150 exposes a portion of the first pole 113, as shown in FIG. 6.

The first protective structure 120 covers the first pole 113, the second pole 114, and the semiconductor layer 112 to protect the transistor 110 during the subsequent preparation of the electroless nickel immersion gold terminal 130 to ensure the integrity and stability of the of the transistor 110.

The first protective structure 120 is provided with a through hole 150, and the through hole 150 can expose a portion of the first pole 113, so as to facilitate the subsequent electrical connection of the electroless nickel immersion gold terminal 130 to the first pole 113, thereby realizing data transmission.

In the embodiment of the present application, the first protective structure 120 includes at least two layers of insulation protective layers, which can both play the role of insulation and protecting the transistor 110.

The first protective structure 120 includes a fourth insulation protective layer 121, a fifth insulation protective layer 122, and a sixth insulation protective layer 123. After the first electrode 113 and the second electrode 114 are formed, the fourth insulation protective layer 121, the fifth insulation protective layer 122, and the sixth insulation protective layer 123 are sequentially deposited on the surfaces thereof by a chemical vapor deposition and coating method. The fourth insulation protective layer 121 covers the insulation dielectric layer 160, the first pole 113, the semiconductor layer 112, and the second pole 114.

The fourth insulation protective layer 121 includes at least one of silicon oxide and silicon nitride, or may be formed of other materials. After the fourth insulation protective layer 121 is formed, it is subjected to an annealing treatment at 240° C. to 300° C. for 30 min to 65 min. The annealing temperature may be 240° C., 260° C., 280° C., 300° C., and the time may be 30 min, 40 min, 45 min, 50 min, 55 min, 60 min, 65 min, etc.

Then the fifth insulation protective layer 122 is coated on the fourth insulation protective layer 121, and the fifth insulation protective layer 122 is a photopolymer resin material with a high sensitivity and high adhesion class.

The sixth insulation protective layer 123 is deposited on the fifth insulation protective layer 122, and the sixth insulation protective layer 123 may be one or more structures of silicon oxide, silicon nitride, and organic insulation film.

Finally, a through hole 150 for exposing a portion of the first pole 113 is formed after the coating glue, exposure, and development, and the dry etching treatment are performed on the fourth insulation protective layer 121, the fifth insulation protective layer 122, and the sixth insulation protective layer 123, and the electroless nickel immersion gold terminal 130 is connected to the first pole 113 through the through hole 150.

Step S500, coating a third metal layer on the first protective structure 120, and patterning the third metal layer to form the electroless nickel immersion gold terminal 130, and the electroless nickel immersion gold terminal 130 is connected to the first pole 113 through the through hole 150, as shown in FIG. 7.

A third metal layer is coated on the sixth insulation protective layer 123 by the magnetron sputtering method. A portion of the metal in the third metal layer falls into the through hole 150, and then the third metal layer is patterned to obtain the electroless nickel immersion gold terminal 130. The third metal layer is made of a composite structure of Cu, Mo, Al, Ti, and Nb. A topmost layer of the electroless nickel immersion gold terminal 130 is a Cu film layer to precipitate Cu in the subsequent electroless nickel immersion gold process, so as to subsequently be soldered to the light-emitting chip.

Patterning the third metal layer includes performing the coating glue, exposure, development, and wet etching and stripping on the third metal layer.

Step S600, forming a second protective structure 140 on the first protective structure 120, and opening a groove 170 in a corresponding portion of the electroless nickel immersion gold terminal 130, and the groove 170 exposes a portion of the electroless nickel immersion gold terminal 130, as shown in FIG. 8.

The second protective structure 140 includes at least two layers of insulation protective layers sequentially provided in a thickness direction of the substrate 100, so as to improve the protective effect on the transistor 110, to ensure that the transistor 110 will not be damaged in the electroless nickel immersion gold process, to improve the working stability of the transistor 110, and further to improve the display stability of the display panel 10.

In an embodiment of the present application, the second protective structure 140 includes a first insulation protective layer 141, a second insulation protective layer 142, and a third insulation protective layer 143 sequentially provided in the thickness direction of the substrate 100. The first insulation protective layer 141 is provided on a side of the sixth insulation protective layer 123 away from the substrate 100, and the first insulation protective layer 141 covers a portion of the electroless nickel immersion gold terminal 130.

The first insulation protective layer 141 and the third insulation protective layer 143 include the same material, and the first insulation protective layer 141 and the third insulation protective layer 143 are made of the material different from that of the second insulation protective layer 142, to improve the protection of the first pole 113, the semiconductor layer 112, the gate 111, and the second pole 114.

The first insulation protective layer 141 includes a single film structure of silicon oxide, silicon nitride, silicon oxynitride, aluminum oxide, or a combination thereof, but is not limited thereto. The second insulation protective layer 142 is an organic film layer, which is mainly a high sensitivity, high adhesion class of photopolymer resin material. The second insulation protective layer 142 mainly serves as a leveling effect to provide a flat surface for the subsequent electroless nickel immersion gold process and welding process. The third insulation protective layer 143 includes a single film structure of silicon oxide, silicon nitride, silicon oxynitride, aluminum oxide, or a combination thereof, but is not limited thereto. That is, the first insulation protective layer 141 and the third insulation protective layer 143 are an inorganic layer, and the second insulation protective layer 142 is an organic layer, and the use of different membrane layers can improve the protective performance of the second protective structure 140, and can better protect the transistor 110.

The method of forming the groove 170 includes coating glue, exposure, development, and dry etching and stripping. Moreover, the cross-sectional area of the groove 170 is gradually increased in a direction from the first insulation protective layer 141 to the third insulation protective layer 143, i.e., an aperture diameter of the groove 170 gradually increases, as shown in FIG. 8, such that fix the light-emitting chip can be fixed in the groove 170, and it ensures that the light-emitting chip will not be skewed, so as to ensure the display effect.

It should be noted that the groove 170 can penetrate the three layers of insulation protective layers by one photolithographic etching, and it is not difficult to implement the process.

The first insulation protective layer 141, the second insulation protective layer 142, and the third insulation protective layer 143 in the second protective structure 140 can improve the protection of the of the transistor 110, thereby avoiding electrical failure of the transistor 110 and corrosion of the metal wires of the transistor 110 under high temperature, high humidity, and acidic conditions in the electroless nickel immersion gold process, and ensuring the integrity and stability of the transistor 110. Moreover, it can effectively limit the region of the electroless nickel immersion gold terminal 130, thereby improving the stability of the electroless nickel immersion gold process.

### Sixth Embodiment

The sixth Embodiment six of the present application provides a display device, the display device includes a light-emitting chip and a display panel 10 described in any one of first to fourth embodiments, and the light-emitting chip is soldered to the copper formed by the electroless nickel immersion gold terminal 130 and the groove 170 through the electroless nickel immersion gold process, so as to control the light emitting state of the light-emitting chip.

In the description of this specification, the description with reference to the terms “some embodiments”, “exemplarily”, etc. means that the specific features, structures, materials, or characteristics described in conjunction with the embodiment or exemplary example are included in at least one embodiment or exemplary example of the present application. In this specification, schematic expressions of the above terms need not be directed to the same embodiment or example. Moreover, the specific features, structures, materials, or characteristics described may be combined in any one or more embodiments or examples in a suitable manner. Moreover, without contradict to each other, those skilled in the art may combine different embodiments or examples and features of different embodiments or examples described in this specification. Although the embodiments of the present application are shown and described above, it is understood that the above embodiments are exemplary and cannot be construed as a limitation of the present application, and that those skilled in the art may make changes, modifications, substitutions and variations of the above embodiments within the scope of the present application, so that any changes or modifications made in accordance with the claims and the specification of the present application shall fall within the scope of the present application.

What is claimed is:

1. A display panel, comprising:
a substrate and a transistor provided on the substrate;
wherein the transistor comprises a gate, a semiconductor layer, a first pole and a second pole, and the gate is provided on a side of the semiconductor layer close to the substrate;
an insulation dielectric layer is provided between the gate and the semiconductor layer, the semiconductor layer is provided on a side of the insulation dielectric layer away from the substrate, and the first pole and the second pole are provided on two sides of the semiconductor layer, respectively;
wherein the display panel further comprises:
a first protective structure, provided on a side of the insulation dielectric layer away from the substrate, wherein the first protective structure is provided with a through hole;
an electroless nickel immersion gold terminal, provided on a side of the first protective structure away from the substrate, wherein the electroless nickel immersion gold terminal is connected to the first pole through the through hole; and
a second protective structure, provided on a side of the first protective structure away from the substrate, wherein the second protective structure is opened with a groove, and the groove exposes at least a portion of the electroless nickel immersion gold terminal.

2. The display panel according to claim 1, wherein the second protective structure comprises at least two layers of insulation protective layers provided sequentially in a thickness direction of the substrate.

3. The display panel according to claim 1, wherein the second protective structure comprises a first insulation protective layer, a second insulation protective layer and a third insulation protective layer provided sequentially in a thickness direction of the substrate, wherein the first insulation protective layer is provided on a side of the first protective structure away from the substrate.

4. The display panel according to claim 3, wherein the first insulation protective layer and the third insulation protective layer comprise same material; and
the second insulation protective layer is made of a material different from that of the first insulation protective layer and the third insulation protective layer.

5. The display panel according to claim 3, wherein the first insulation protective layer or the third insulation protective layer comprises at least one of silicon oxide, silicon nitride, silicon oxynitride, and aluminum oxide; and
the second insulation protective layer comprises an organic film layer.

6. The display panel according to claim 5, wherein a cross-sectional area of the groove is increased gradually in a direction from the first insulation protective layer to the third insulation protective layer.

7. The display panel according to claim 1, wherein the first protective structure comprises at least two layers of insulation protective layers.

8. The display panel according to claim 1, further comprising a third protective structure provided between the first protective structure and the second protective structure, and the third protective structure covers a portion of the electroless nickel immersion gold terminal.

9. The display panel according to claim 1, wherein the semiconductor layer has a carrier concentration of 5 to 30 cm²/V*S.

10. The display panel according to claim 1, wherein the insulation dielectric layer is one of silicon nitride and silicon oxynitride close to the gate.

11. The display panel according to claim 8, wherein the third protective structure is a metal oxide protective layer made of the same material as the semiconductor layer.

12. The display panel according to claim 3, wherein the first insulation protective layer and the third insulation protective layer comprises the same material, and the first insulation protective layer and the third insulation protective layer are made of a material different from that of the second insulation protective layer.

13. The display panel according to claim 3, wherein the display panel comprises a plurality of transistors provided on the substrate, and one transistor corresponds to one sub-pixel.

14. A method of preparing a display panel, comprising:
forming a first metal layer on a substrate and patterning the first metal layer to form a gate;
forming an insulation dielectric layer and a semiconductor layer sequentially on the substrate, wherein the insulation dielectric layer covers the gate;
depositing a second metal layer on the insulation dielectric layer and the semiconductor layer, and patterning the second metal layer to form a first pole and a second pole;
forming a first protective structure on the insulation dielectric layer and the semiconductor layer, and opening a through hole in a portion corresponding to the first pole, wherein the through hole exposes a portion of the first pole;
coating the first protective structure with a third metal layer, and patterning the third metal layer to form an electroless nickel immersion gold terminal, wherein the electroless nickel immersion gold terminal is connected to the first pole through the through hole; and
forming a second protective structure on the first protective structure and opening a groove in a portion corresponding to the electroless nickel immersion gold terminal, wherein the groove exposes a portion of the electroless nickel immersion gold terminal.

15. The method of preparing the display panel according to claim 14, wherein the second protective structure comprises at least two layers of insulation protective layers provided sequentially in a thickness direction of the substrate.

16. The method of preparing the display panel according to claim 14, wherein the second protective structure comprises a first insulation protective layer, a second insulation protective layer and a third insulation protective layer provided sequentially in a thickness direction of the substrate, wherein the first insulation protective layer is provided on a side of the first protective structure away from the substrate.

17. The method of preparing the display panel according to claim 16 wherein the first insulation protective layer and the third insulation protective layer comprise same material; and
the second insulation protective layer is made of a material different from that of the first insulation protective layer and the third insulation protective layer.

18. The method of preparing the display panel according to claim 16, wherein the first insulation protective layer or the third insulation protective layer comprises at least one of silicon oxide, silicon nitride, silicon oxynitride, and aluminum oxide; and
the second insulation protective layer comprises an organic film layer.

19. The method of preparing the display panel according to claim 18, wherein a cross-sectional area of the groove is increased gradually in a direction from the first insulation protective layer to the third insulation protective layer.

20. A display device, comprising a light-emitting chip and the display panel according to claim 1, wherein the light-emitting chip is connected to the electroless nickel immersion gold terminal through the groove.
